(19) United States
(12) Patent Application Publication
(10) Pub. No.: US 2020/0017960 A1
(43) Pub. Date: Jan. 16, 2020

(54) PLASMA-ENHANCED CHEMICAL VAPOR DEPOSITION OF CARBON-BASED COATINGS ON SURFACES

(71) Applicant: DURALAR TECHNOLOGIES, LLC, Tucson, AZ (US)

(72) Inventors: Andrew Tudhope, Tucson, AZ (US); Salvatore Gennaro, Tucson, AZ (US)

(21) Appl. No.: 16/316,004

(22) PCT Filed: Jul. 5, 2017
(86) PCT No.: PCT/US17/40695

§ 371 Date: Jan. 7, 2019

Related U.S. Application Data
(60) Provisional application No. 62/358,286, filed on Jul. 5, 2016.

(51) Int. Cl. C23C 16/04; C23C 16/02; C23C 16/27; C23C 16/515; H05H 1/46

(52) U.S. Cl. CPC C23C 16/045; C23C 16/0272; H05H 1/46; C23C 16/515; C23C 16/276

(57) ABSTRACT

Systems and methods for producing carbon-based coatings featuring diamond-like carbon (DLC) structures on the internal surfaces of cylindrical or tube-like components is disclosed. The methods feature the use of plasma-enhanced chemical vapor deposition (PECVD) to provide a generally uniform coating on the surface. Longitudinally homogeneous plasma is ignited directly inside the tube-like component. A bipolar pulse with a reverse active plasma step is used. The pressure and bias voltage are selected so as to cause the deposition of a carbon-based coating on the inner surface.

### FIELD OF THE INVENTION

The present invention relates to methods and compositions for protecting surfaces, such as internal surfaces of bores of shotguns, from corrosion or damage. More particularly, the present invention relates to methods and compositions for plasma-enhanced chemical vapor deposition of carbon-based coatings on surfaces, such as the internal surfaces of tube-like components and/or of components positioned on the surface of the tube-like component.

### BACKGROUND OF THE INVENTION

A correlation exists between the corrosion and wearing problems of a shotgun barrel. During the explosion of the gunpowder and the firing of the projectile, the internal surface of the bore experiences very high temperatures (around 1400° C. in a matter of milliseconds); meanwhile, the bore has to support the load of the actual bullets or shots sliding through it. The effect of the thermal heating can result in the cracking of the bore coating due to the different thermal coefficient with the substrate. When exposing the micro-cracks to the firing hot gases and environment atmosphere, corrosion events start taking place. This can lead to more severe degradation of the coating adhesion on those areas. When subjected to the stress of the projectile motion, parts of the coating can delaminate, exposing new bore surfaces. The overall effect is the degradation of the quality of the internal surface of the bore that, in turn, leads to decreasing performance (e.g., muzzle velocity, target dispersion) of the weapon. In some instances, the bore itself might break down due to mechanical weakening.

Historically, the problem has been addressed by using the process of chromium (“Cr”) plating of the bores (e.g., see U.S. Pat. No. 1,886,218, the disclosure of which is incorporated herein in its entirety). The protective film is effective in increasing the lifetime of the gun barrel by reducing the effects of the severe environment represented by the hot propellant gases developed in the explosion of the gunpowder and the mechanical effects induced by the sliding passage of the projectile inside. However, the industrial process to produce these coating requires the use of chemical substances (e.g., hexavalent Cr, a known carcinogen) that have been demonstrated to be pollutants and hazardous to human health. Also, dealing with hazardous chemicals, such as hexavalent Cr, can be very costly for companies.

With particular regard to the internal surfaces of hollow (bores and tube-like) components, U.S. Pat. Nos. 3,523,035 and 5,039,357 disclose protecting the internal surface of gun barrels through deposition of doped titanium carbide or by nitriding and nitrocarburizing the surfaces in a fluidized bed furnace. U.S. Pat. No. 6,511,710 teaches the use of a plasma torch to melt desired substances and addresses them inside the barrel to deposit a protective coating. U.S. Pat. No. 8,105,660 teaches the production of diamond-like carbon (“DLC”) coatings on internal tubes by means of a hollow cathode effect. U.S. Pat. No. 8,715,789 teaches a modification on U.S. Pat. No. 8,105,660 wherein a set of electrodes is inserted into the barrel (the coating still occurs using a hollow cathode effect). U.S. Pat. No. 4,641,450 relates to the straining of the coating to make it endure the stress associated with the differential thermal expansion between the substrate material and the coating due to the heat generated in the firing process. U.S. Pat. No. 5,728,465 relates to the use of DLC coatings or doped DLC coatings for producing a protective coating on metallic parts. U.S. Pat. No. 8,112,930 discloses methods for protecting firearms with corrosion-resistant coatings.

Despite having a very low thermal expansion, carbon (“C”)-based coatings (e.g., DLC, amorphous DLC (“ADLC”)) exhibit extremely good wearing properties and have a low friction coefficient. This is particularly true when increasing the amount of carbon atoms with hybridization sp3 (diamond structure) with respect to those with hybridization sp² (graphitic structure). Moreover, such a kind of C-based coatings have the advantage of being chemically inert and, hence, resistant to corrosion.

### SUMMARY OF THE INVENTION

The present invention features methods, systems, and compositions for producing a carbon-based (“C-based”) coating, e.g., a carbon-based coating comprising at least some degree of DLC structures, on surfaces such as the internal surfaces of the bore of a shot gun barrel or other to tubes and pipes like hollow components and/or surfaces of components located in the internal cavity of tube-like component used as an outer shell, using plasma-enhanced chemical vapor deposition (“PECVD”). The present invention also features devices and systems for performing the present methods.

Briefly, plasma is generated inside the tube or pipe component. Pressure is controlled within the tube or pipe component and controlled amounts of gases are introduced to generate and sustain the desired plasma. The plasma is ignited through the application of a direct current (“DC”) bias to the tube with an internally placed center electrode, which runs coaxially throughout a portion of the length of the tube or pipe component. Hereinafter, the center electrode is alternately referred to as a wire, an electrically conductive wire, or an anode. Alternatively, the center electrode may run the entire length of the tube or pipe component. The component itself acts as a cylindrical electrode of the system. The pressure and bias voltage and pulse modulation are selected so as to cause the deposition of the C-based coating on the inner surface. The coating has a generally uniform thickness across the length of the tube or pipe component. The coating may provide for uniform mechanical resistance (e.g., to erosion, corrosion, etc.) across the length of the tube or pipe component. In preferred embodiments, the present invention allows for the tuning of the properties of the coating by the adjustment of the process parameters.

The present invention provides for the coating of an inner surface of an electrically conductive hollow tube (i.e., the tube or pipe component), interchangeably referred to herein as a “hollow tube”, “tube”, “component”, or “pipe-like component”. For illustrative purposes, the hollow tube described herein may be a barrel, such as a gun barrel. However, it is to be understood that the tube can be any tube in which a coating is desired to be deposited on its inner surface, and is not limited to barrels. Other examples of tubes that may be use in accordance with the present invention can include, but are not limited to, shock absorbers for vehicles, pipelines, and glass tubes for light bulbs.

In exemplary embodiments, a multi-component coating system, utilizing an external vacuum chamber, simultaneously coats the inner surfaces of multiple hollow tubes disposed within the vacuum chamber. In another embodiment, a single component coating system comprises a hollow tube, whose inner surface is to be coated, functionally acting as a vacuum chamber. The latter embodiment was implemented at a prototyping level, and as such, all provided examples of power and gas flow values cited herein refer to experimental values acquired via the single component coating system. For application to the multi-component coating system, said values must be scaled up according to the size and number of hollow tubes coated.

In some embodiments, the multi-component coating system, (or, alternately, the “apparatus”) comprises a first end cap, composed of a first electrically insulating material, having an opening for a gas supply; a second end cap, composed of a second electrically insulating material; and an electrically conductive wire passing through the center of the first end cap. The hollow tube may be placed between the first and the second end caps. Further, the wire may be disposed in the center of the hollow tube. In other embodiments, the gas supply is connected to the opening of the hollow tube, for filling the hollow tube with a gas. This gas may be contained within the hollow tube by the first end cap and the second end cap. A pulse biasing system, capable of generating a series of electrical pulses, may additionally comprise the apparatus. In an embodiment, the pulse biasing system has a negative output connected to the hollow tube and a positive output connected to the wire. The hollow tube may act as a cathode and the wire may act as an anode.

In preferred embodiments, the gas may comprise a material which, when ignited by an electrical pulse, causes a carbon-based coating to be deposited on the inner surface of the hollow tube.

Consistent with previous embodiments, the pulse biasing system may deliver a series of positive and negative electrical pulses to the wire and to the hollow tube. In this way, an electrical field is generated between the hollow tube and the wire for igniting the gas, resulting in the deposition of the carbon-based coating onto the inner surface of the hollow tube. In some embodiments, the wire is centralized, (i.e., disposed coaxially along a center longitudinal axis within the hollow tube), by a weight. The weight may be placed at a lower edge of the wire or disposed within the second end cap.

In an embodiment, the material comprising the gas is a mixture of gaseous chemical components. A gas mixer may be connected between the gas supply and the hollow tube for mixing the gaseous chemical components according to a fixed ratio. An exemplary mixture of gaseous chemical components may comprise argon (“Ar”), methane, and tetramethylsilane (“TMS”).

In an additional embodiment, the apparatus may comprise a plurality of top end caps capable of holding a plurality of hollow tubes; a plurality of bottom end caps capable of holding the weight of and centralizing a plurality of wires, where each wire passes through a center of one of the plurality of top end caps; a gas splitter, connected between the gas mixer and the hollow tubes, capable of distributing an equal amount of gas to each hollow tube; and a plurality of gas flow controllers, each connected between the gas splitter and one of the plurality of top end caps.

In one embodiment, the apparatus comprises an anode splitter electrically connected between the positive output of the pulse biasing system and the wires. In an alternate embodiment, the apparatus comprises a cathode splitter electrically connected between the negative output of the pulse biasing system and the hollow tubes. In still another alternative embodiment, the apparatus comprises both the anode and cathode splitters.

In further embodiments, the pulse biasing system delivers a series of positive and negative electrical pulses to the anode splitter and/or to the cathode splitter. The series of positive and negative pulses may be applied equally to each hollow tube and to each wire. An electrical field is thus generated between each hollow tube and the wire disposed therein. The gas splitter may deliver gas to each gas flow controller, which may be either open or closed. If a gas flow controller is open, the hollow tube operatively coupled to said gas flow controller (via a top end cap) is filled with gas. Thus, when the electrical field is generated, the gas is ignited and a carbon coating is deposited onto the inner surface of the hollow tube.

In some embodiments, the series of positive and negative electrical pulses are separated by an off time, which can vary with the length and/or height of the hollow tube. In other embodiments, the off time can vary with a power level, of the plurality of power levels.

According to another embodiment, the present invention features a method of coating an inner surface of a conductive hollow tube. The method may comprise extending a conductive wire through a center of the conductive hollow tube; filling the conductive hollow tube with a gas from a gas supply, where the gas comprises a mixture of chemical components whose igniting causes a carbon-based coating to be deposited on the conductive hollow tube; and supplying a bipolar voltage pulse to the conductive hollow tube and to the wire. The bipolar voltage pulse is capable of igniting the gas, resulting in the deposition of the carbon-based coating onto the inner surface of the conductive hollow tube. The present method may be utilized by any of the embodiments of the previously presented apparatuses.

In supplementary embodiments, the present invention features a method for coating the inner surfaces of a plurality of conductive hollow tubes. The method may comprise linearly aligning the plurality of conductive hollow tubes, end to end, so as to fluidly connect each conductive hollow tube to another conductive hollow tube and so as to ensure that the center longitudinal axis of each conductive hollow tube is aligned; passing a conductive wire through a center of each conductive hollow tube; filling the plurality of conductive hollow tubes with a gas from a gas supply, where the gas comprises a mixture of chemical components whose igniting causes a carbon-based coating to be deposited on each conductive hollow tube; and supplying a bipolar voltage pulse to the plurality of conductive hollow tubes and to the conductive wire. The bipolar voltage pulse is capable of igniting the gas, resulting in the depositing of the carbon-based coating onto the inner surface of each conductive hollow tube.

In some embodiments, the wire is centralized, by a weight. The weight may be applied at a lower end of the conductive wire. In other embodiments, the weight may be disposed inside an end cap attached at the lower end of the bottom-most tube.

In additional embodiments, a gas mixer is connected between the gas supply and the plurality of conductive hollow tubes for mixing the mixture of chemical components according to a fixed ratio. The mixture of chemical components may comprise inert gases and PECVD precursors. Further, the bipolar voltage pulse may be supplied by a pulse biasing system capable of outputting a series of pulses at a plurality of power levels. Each pulse may be separated by an off time, which varies with a length or height of a hollow tube. In other embodiments, the off time also varies with a power level, of the plurality of power levels.

One of the unique and inventive technical features of the present invention is the provision of a periodic reversal of the voltage field applied to a hollow component during the deposition process. Without wishing to limit the present invention to any theory or mechanism, it is believed that this technical feature surprisingly and advantageously provides for the deposition of a coating onto a center electrode coaxially disposed within the hollow component. The periodic reversal of the applied voltage field also allows for a uniform deposition thickness to progress along the length of the hollow component (acting as a cylindrical electrode) where the plasma is most active. Furthermore, the center electrode is placed under constant tension so as to maintain its axial symmetry (coaxial position) with the interior of the hollow component (since the center electrode expands and stretches under a heat load during the deposition process). Without wishing to limit the present invention to any theory or mechanism, it is believed that when the plasma ignites in the tube, it is unlikely to be of uniform density and intensity. Gas is introduced at one end of the hollow component and diffuses toward the opposite end. Thus, there is a gas density gradient along the hollow component. The electric field in the hollow component is likewise unlikely to be uniform since the hollow component may be a resonant cavity at radio frequencies. By periodically reversing the deposition between the center electrode and the hollow component, (thus allowing a deposit to build up on the center electrode and the inner surface of the hollow component), the center electrode may become gradually less effective in the regions of greatest plasma intensity and deposition rate. This may produce a quenching of the deposition action in the regions that have already received most of the deposition, and may allow the most active deposition region to migrate toward areas that had been relatively less active along the length of the tube. The result may become a more uniform thickness of deposition coating along the length of the interior of the hollow component. None of the presently known prior references or work have the unique aforementioned inventive technical features of the present invention, nor the feature of an anode inserted within the component to be coated.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE DRAWINGS

FIG. 1A shows a schematic representation of a multi-component coating system for performing the methods of the present invention.

FIG. 1B shows a schematic representation of the single component coating system.

FIG. 1C shows an embodiment of the centering component of the present invention.

FIG. 2 shows the process-type for a 28″ long 2″ wide specimen.

FIG. 3 shows the coating thickness profile (μm) along the pipe (i.e., the hollow tube) length (mm).

FIG. 4 shows a detailed top view of the top external portion of the multi-component coating system featuring a gas splitting system (comprising a common gas line, a gas splitter, and a single gas line).

FIG. 5 shows a 3-dimensional view of the top external portion of the multi-component coating system featuring gas splitting systems.

FIG. 6 shows an exemplary pulse profile according to one embodiment of the present invention.

FIG. 7 shows an exemplary pulse profile according to one embodiment of the present invention.

FIG. 8 shows an alternative schematic of the present invention. Both the multi-component coating system and the single component coating system may employ this approach.

### DETAILED DESCRIPTION OF THE INVENTION

Following is a list of elements corresponding to a particular element referred to herein:
1 vacuum chamber
2 vacuum sensor
3 throttle valve
4 vacuum pump
5 top insulating component, dummy pipe-like component, anode centering
top component
6 hollow tube
7 anode
8 bottom insulating component, dummy pipe-like component, anode centering bottom component
9 mechanical tool or weight
10 DC power supply
11 cathodes electrical connection
12 anodes electrical connection
13 pulser unit
14 common cathode power line
15 common anode power line
16a anode splitter
16c cathode splitter
17a single anode electrical connections
17c single cathode electrical connections
18 gas supply
19 gas lines
20 mixing box
21 common gas line
22 gas splitter
23 single gas line
24 needle valve
25 mass flow controller or flow meter
50,60 bipolar pulse
51 bipolar pulse period
61 first discharge interval
62 second discharge interval
63 third discharge interval
65 first off time interval
66 second off time interval
67 positive pulse
68 negative pulse
101 pipe-like hollow component
102, 103 dummy part
104 insulating top cap
105 insulating bottom cap
106 anode
107 pressure sensor
108 throttle valve
109 pumping system
109a roughing pump
109b root pump
110 bottom vacuum component
111 gas panel
112 gas cylinders
113, 115 gas valves
114 mass flow controllers
116 gas mixing box
117 common gas line
118, 119 DC power supply
120 pulser unit
121 anode electrical connection
122 cathode electrical connection
123 preferred positioning of the anode centering component
124 a weight or mechanical tool for anode straightening and centering
201 first off time interval
202 second off time interval

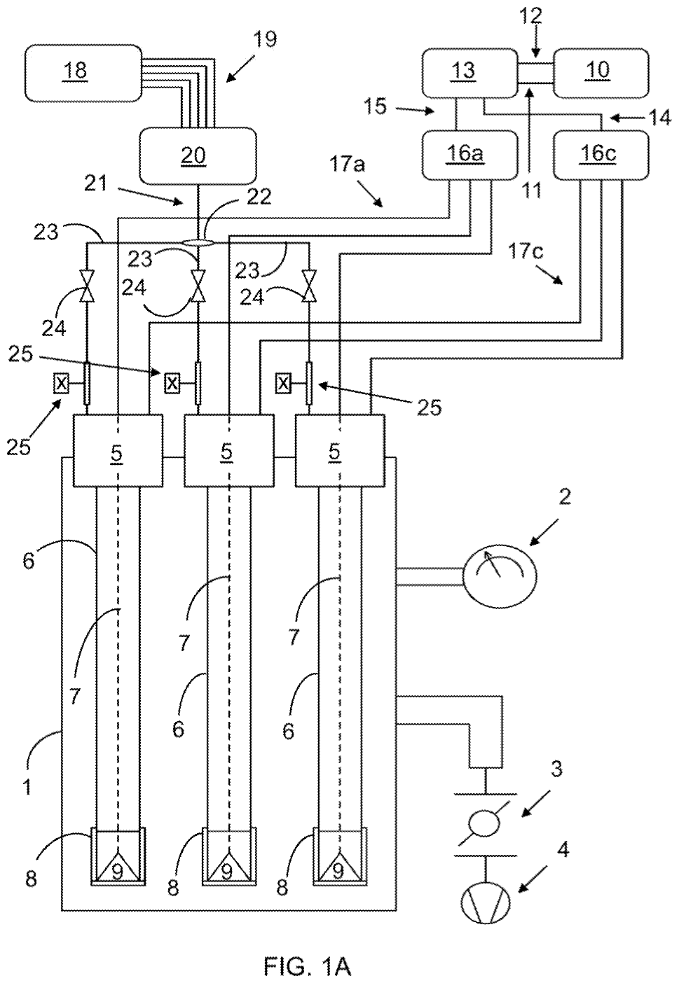

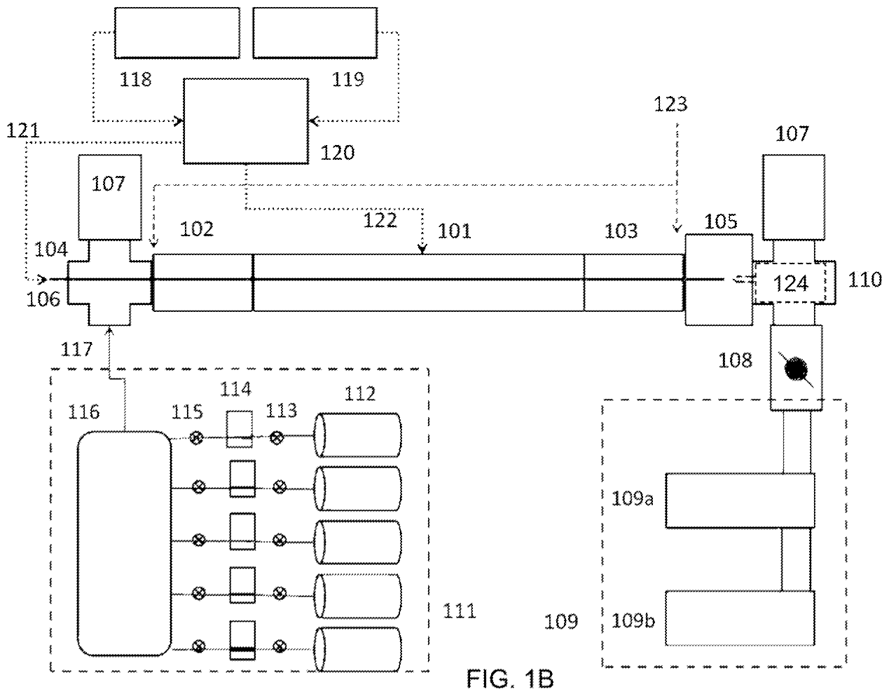

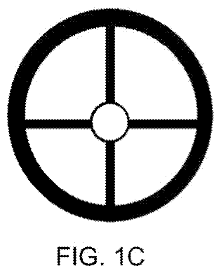

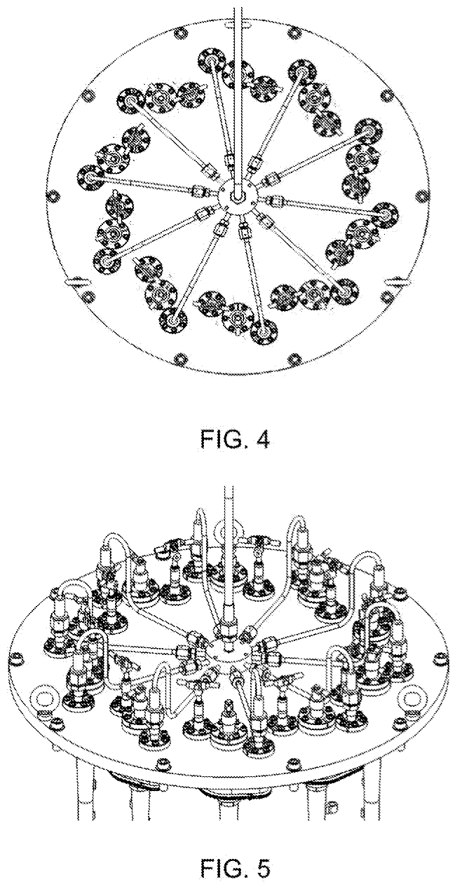

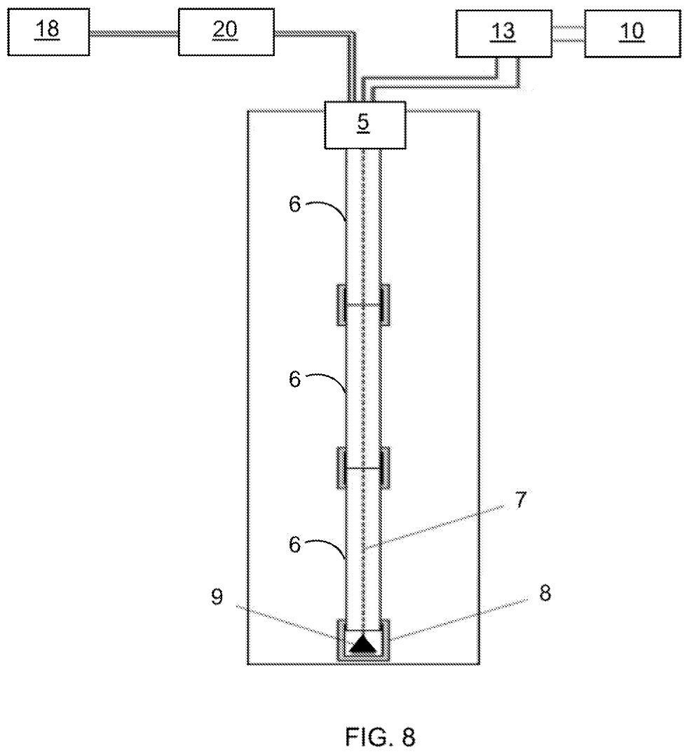

Referring now to FIGS. 1A-8, the present invention features an apparatus for coating an inner surface of an electrically conductive hollow tube (6) disposed within a vacuum chamber (1). In some embodiments, apparatus comprises a first end cap (5), composed of a first electrically insulating material, having an opening for a gas supply; a second end cap (8), composed of a second electrically insulating material; and an electrically conductive wire passing through the center of the first end cap (5). The hollow tube (6) may be placed between the first (5) and the second (8) end caps. Further, the wire (7) may be disposed in the center of the hollow tube (6). In other embodiments, the gas supply (18) is connected to the opening of the hollow tube (6), for filling the hollow tube (6) with a gas. This gas may be contained within the hollow tube (6) by the first end cap (5) and the second end cap (8). A pulse biasing system (13), capable of generating a series of electrical pulses, may additionally comprise the apparatus. In an embodiment, the pulse biasing system (13) has a negative output connected to the hollow tube (6) and a positive output connected to the wire (7). The hollow tube (6) may act as a cathode and the wire (7) may act as an anode.

In preferred embodiments, the gas may comprise a material which, when ignited by an electrical pulse, causes a carbon-based coating to be deposited on the inner surface of the hollow tube (6).

Consistent with previous embodiments, the pulse biasing system (13) may deliver a series of positive and negative electrical pulses to the wire (7) and to the hollow tube (6). In this way, an electrical field is generated between the hollow tube (6) and the wire (7) for igniting the gas, resulting in the deposition of the carbon-based coating onto the inner surface of the hollow tube (6). In some embodiments, the wire (7) is centralized, (i.e., disposed coaxially along a center longitudinal axis within the hollow tube (6)), by a weight. The weight may be placed at a lower edge of the wire (7) or disposed within the second end cap (8).

In an embodiment, the material comprising the gas is a mixture of gaseous chemical components. A gas mixer (20) may be connected between the gas supply (18) and the hollow tube for mixing the gaseous chemical components according to a fixed ratio. An exemplary mixture of gaseous chemical components may comprise Ar, methane, and TMS.

In an additional embodiment, the apparatus may comprise a plurality of top end caps capable of holding a plurality of hollow tubes (6); a plurality of bottom end caps capable of holding the weight of and centralizing a plurality of wires (7), where each wire passes through a center of one of the plurality of top end caps; a gas splitter, connected between the gas mixer (20) and the hollow tubes (6), capable of distributing an equal amount of gas to each hollow tube; and a plurality of gas flow controllers (24,25), each connected between the gas splitter and one of the plurality of top end caps.

In one embodiment, the apparatus comprises an anode splitter (16a) electrically connected between the positive output of the pulse biasing system (13) and the wires (7). In an alternate embodiment, the apparatus comprises a cathode splitter (16c) electrically connected between the negative output of the pulse biasing system (13) and the hollow tubes (6). In still another alternative embodiment, the apparatus comprises both the anode (16a) and cathode (16c) splitters.

In further embodiments, the pulse biasing system (13) delivers a series of positive and negative electrical pulses to the anode splitter (16a) and/or to the cathode splitter (16c). The series of positive and negative pulses may be applied equally to each hollow tube and to each wire. An electrical field is thus generated between each hollow tube and the wire disposed therein. The gas splitter may deliver gas to each gas flow controller, which may be either open or closed. If a gas flow controller is open, the hollow tube operatively coupled to said gas flow controller (via a top end cap) is filled with gas. Thus, when the electrical field is generated, the gas is ignited and a carbon coating is deposited onto the inner surface of the hollow tube.

In some embodiments, the series of positive and negative electrical pulses are separated by an off time, which can vary with the length and/or height of the hollow tube. For the single component coating system, the pulse biasing system (13) is capable of outputting pulses at a plurality of power levels in the range of 10 W to 500 W. Power levels for the multi-component coating system may vary according to the number of hollow tubes (6) to be coated and/or according to the size of the hollow tubes (6). In other embodiments, the off time can vary with a power level, of the plurality of power levels.

According to another embodiment, the present invention features a method of coating an inner surface of a conductive hollow tube (6). The method may comprise extending a conductive wire (7) through a center of the conductive hollow tube (6); filling the conductive hollow tube (6) with a gas from a gas supply, where the gas comprises a mixture of chemical components whose igniting causes a carbon-based coating to be deposited on the conductive hollow tube (6); and supplying a bipolar voltage pulse to the conductive hollow tube (6) and to the wire (7). The bipolar voltage pulse is capable of igniting the gas, resulting in the deposition of the carbon-based coating onto the inner surface of the conductive hollow tube (6). The present method may be utilized by any of the embodiments of the previously presented apparatuses.

In supplementary embodiments, the present invention features a method for coating the inner surfaces of a plurality of conductive hollow tubes (6). The method may comprise linearly aligning the plurality of conductive hollow tubes (6), end to end, so as to fluidly connect each conductive hollow tube to another conductive hollow tube and so as to ensure that the center longitudinal axis of each conductive hollow tube is aligned; passing a conductive wire (7) through a center of each conductive hollow tube; filling the plurality of conductive hollow tubes (6) with a gas from a gas supply, where the gas comprises a mixture of chemical components whose igniting causes a carbon-based coating to be deposited on each conductive hollow tube; and supplying a bipolar voltage pulse to the plurality of conductive hollow tubes (6) and to the conductive wire (7). The bipolar voltage pulse is capable of igniting the gas, resulting in the depositing of the carbon-based coating onto the inner surface of each conductive hollow tube.

In some embodiments, the wire (7) is centralized, (i.e., disposed coaxially along a center longitudinal axis within a conductive hollow tube), by a weight (9). The weight (9) may be applied at a lower end of the conductive wire (7). In other embodiments, the weight (9) may be disposed inside an end cap attached at the lower end of the bottom-most tube.

In additional embodiments, a gas mixer (20) is connected between the gas supply (18) and the plurality of conductive hollow tubes (6) for mixing the mixture of chemical components according to a fixed ratio. The mixture of chemical components may comprise inert gases and PECVD precursors. Further, the bipolar voltage pulse (50, 60) may be supplied by a pulse biasing system (13) capable of outputting a series of pulses at a plurality of power levels. Each pulse may be separated by an off time (65, 66, 201, 202), which varies with a length or height of a hollow tube. In other embodiments, the off time (65, 66, 201, 202) also varies with a power level, of the plurality of power levels (ranging, for example, from 30 watts to 500 watts per conductive hollow tube).

In some embodiments, the method of the present invention may comprise one or more of the following steps: (a) generating reduced pressure conditions (e.g., in the range of 1-50 mTorr) within the hollow tubes (6) to be coated; (b) introducing the gas needed for plasma generation (e.g., at an indicative rate up to 200 sccm); (c) stabilizing the internal pressure for plasma generation (e.g., at a value of about 200 mTorr); (d) igniting a plasma by biasing the walls of the hollow tube (which acts as a cylindrical electrode) positively and negatively with respect to an internally inserted conducting wire (7) (which acts as the center electrode) with bias voltage (e.g., in the range of 150-1000 V); and (e) introducing the required precursors (e.g., a hydrocarbon CₓH_{y}, such as but not limited to acetylene) in gaseous phase (e.g., at an indicative rate of 100-200 sccm) for the deposition. During the plasma generation and deposition, the bias application is pulsed with a given frequency to stabilize coating conditions. The indicative gas flow values stated refer to the processing of a single hollow tube (6). Actual gas flow values may vary, proportionally, to the number of hollow tubes (6) to be coated and may be affected by the size of the hollow tubes (6).

One or more of the above steps may adopt one or more of the following steps and/or materials: The precursor might be chosen among the gas hydrocarbon such as CH₄ or C₂H₂. The present invention is not limited to the aforementioned precursors and does not exclude the option of using special liquid precursors, such as diamondoid, for maximizing the DLC fraction of the growing coating. The percentage of the given precursors with respect to the other mixing gases may be kept in the range of 10% to 100%, with an operative pressure (e.g., ranging from 10 mTorr to 300 mTorr). In some embodiments, the bias voltage can range from 150 V up to 1000 V. In other embodiments, the pulse frequency of the bias application may range between 0.5 kHz and 20 kHz. Additionally, the process may also include a step of evaporation of a specific reactive gas metal or metalloid containing (e.g., TMS). The process may include a step of attaching an electrode, acting as a cathode, to the surface of the hollow tube to be coated. The process may also include the step of attaching an electrode to a wire or wire like conducting component, acting as a center electrode (i.e., an anode). The wire or wire like component may be inserted into the hollow tube (over a portion of the hollow tube or over the whole length of it) along a central longitudinal axis of the tube. The process may require hardware to insulate the center electrode from the cylindrical electrode.

### Details of the Single and Multi-Component Coating Systems

Referring to FIG. 1A, a non-limiting example of an embodiment of the multi-component coating system is shown. It is understood that this embodiment is a single configuration and other configurations are possible (e.g., by increasing or decreasing the number of insulating components, anodes, pipe-like components, anode or cathode connections, gas lines, needle valves, mass flow controllers, etc.) A conductive pipe-like component (6), having a wire (7) centrally disposed therein, is disposed in a vacuum chamber (1). The component and the wire (7) are connected to a DC power supply (10) through a pulser unit (13), which applies a pulsed bias to the component (6) and to the wire (7). The wire may alternatively be a wire-like conducting component. The component (6) acts as a cylindrical electrode, while the wire (7) acts as a center electrode. The pulsed bias is used to:
a) create a plasma inside the component,
b) attract the positively ionized species of the plasma towards the internal surface of the component to be coated,
c) allow ion bombardment of the growing coating to improve film properties, such as adhesion, density, hardness, stress level, etc.,
d) allow discharge of the coating of the cylindrical electrode (particularly relevant for partly insulating coating in order to avoid charge build up which may result in unexpected working conditions and arcing),
e) allow freshly introduced un-reacted gas to refill the component by tuning the frequency of the pulses, and
f) allow progressive coating of the center electrode (reverse pulsing) with the aim of improving the overall uniformity of the coating in terms of thickness and coating (plasma) chemistry along the whole length of the component (6).

In some embodiments, a bipolar pulse is applied to increase the efficiency of charge dissipation. During the short negative pulse, the plasma is generated and the positive species are accelerated towards the surface of the component (acting as a cylindrical electrode) creating the deposit. During the reverse short positive pulse, plasma is forced to behave the opposite way. The electrons are attracted towards the component surface (allowing for charge compensation) and a progressive coating is produced on the center electrode (7). The main effect is a progressive increase in the resistivity of the center electrode. Without wishing to limit the present invention to any theory or mechanism, it is believed that this progressive increase of the resistivity of the center electrode is beneficial for the regular consumption of the plasma chemistry along the whole length of the component to be coated. During the off time, gas is allowed to refill the vacuum chamber (1). In some embodiments, the use of a constantly changing duty time (e.g., changing constantly the off time after the reverse pulse) and the progressive coating of the center electrode may help achieve plasma chemistry uniformity along the whole component. This may allow the achievement of coatings with a relatively uniform thickness profile and a relatively uniform chemical nature along the whole length of the component.

During the discharge process, the center electrode (7) is heated and may deform and cause the uniformity of the discharge between the center electrode (7) and the cylindrical electrode (6). Various means may be taken to keep the center electrode (7) in position. For example, the center electrode (7) and the cylindrical electrode (6) may be positioned vertically with a weight (9) hung at a lower end of the center electrode (7) to keep it straight. In another example, a stretch force may be applied to the center electrode (7) to keep it straight. The stretch force may be from a compressed spring or other mechanic device. The plasma may be generated by means of a high electric field created between the component (6) and the wire (7). The pulser unit (13) may be connected to an anode splitter and/or cathode splitter.

FIG. 1B is a non-limiting example of an embodiment of the single component coating system. It is understood that this embodiment is a single configuration and other configurations are possible (e.g., by increasing or decreasing the number of insulating components, anodes, anode or cathode connections, gas lines, needle valves, mass flow controllers, etc.) Pressure sensors may be placed either on the bottom insulating component (105) and/or on the bottom vacuum component (111) in order to monitor and control pressure. The center electrode and the cylindrical electrode are insulated from each other (and from other components) by means of insulating components (104) and (105).

The following description is valid for both the single component coating system and the multi-component coating system unless otherwise noted. The gas needed for deposition may be supplied by means of a gas panel (18,110). In some embodiments, the gas travels from the gas panel (18,110) to a mixing box (20,116) and is then transported by means of a gas line (21,122) and injected into the component (6,101). Coupled to the component (6,101) is a pumping system (4, 109) comprising pumps for roughing pumping and high-vacuum pumping (109a,109b) to drive the gas through the component (6,101) and provide the desired operating pressure via a throttle valve (3,108).

The gas panel (18, 111) may comprise gas cylinders (112) for storing the one or more gases or liquids to be used. The gas cylinders provide gas streams via mass flow controllers (“MFCs) (114) controlled by closing valves. Further, the gas may be injected into the component (101) through an aperture in the insulating component (105).

In the case of the multi-component coating system, a gas splitter (22) splits equal amount of gases to each component (6).

In some embodiments, the top and bottom of the component (6,101) is surrounded by sacrificial dummy pipe-like components (5,8,102,103). In some embodiments, the dummy pipe-like components comprise a material similar to that of the component (6,101) and/or a size (e.g., external diameter, internal diameter) that is similar to that of component (6,101). The dummy pipe-like components may help allow the plasma density to not be perturbed in the vicinity of the edges of a region of interest.

During the process, the plasma generation and electron injection heats the center electrode (7,106). This may have the consequence of increasing its flexibility, which could result in the bending (and misalignment) of the center electrode (7,106). If the center electrode (7,106) is not aligned appropriately, uniform plasma conditions may not be created (and differential bombardment energy all over the internal surface diameter of the component (6,101) would be created), leading to non-homogeneous properties of the deposit. It may even cause an electrical shortcut with the component (6,101). To help prevent this, in some embodiments one or more mechanical tools (9,124) are attached (e.g., by means of a material with good thermal and electrical insulating properties, e.g., glass fibers) to the bottom end of the center electrode (7,106). The center electrode (7,106) is thus constantly under tension by the mechanical tool (9,124) so that it can remain aligned appropriately (e.g., coaxially) with respect to the component (6, 101). In other embodiments, the mechanical tools (9,124) are centering components (see FIG. 1C) composed of an insulating material (e.g., Teflon). In a non-limiting example of an embodiment of the multi-component coating system, the centering components may be placed at the junction between the top or bottom insulating component (5, 8) and the component (6). In a non-limiting example of the of an embodiment of the single component coating system, the centering components may be placed at the junction between the insulating top cap (104) and the dummy part (102) or between the dummy part (103) and the insulating bottom cap (105). The centering component is not limited to the configuration shown in FIG. 1C.

In some embodiments, before the coating takes place, the component (6,101) is heated, e.g., to a temperature ranging from 100 to 450° C., by means of resistors. The heating is performed by a heating system in the proximity of the component (6,101) (e.g., the heating system can be placed around the component (101) in case of the single component coating system or inserted into the vacuum chamber (1) in the case of the multi-component coating system). A low flow rate inert gas (e.g. Ar) may be flowing through the component (6,101) during said heating. In some embodiments, the heating system is also used to keep the component (6,101) warm, (e.g., during the initial stage of the PECVD process), to improve the adhesion of the coating. In some embodiments, the present invention features a step of plasma sputter-cleaning and/or surface micro-texturing. This may help further clean the interior surface of the component (6,101) and may improve the gripping of the incoming ions to the bare metallic surface of the component (6,101).

In some embodiments, to achieve the sputter cleaning, the single component coating system and/or the multi-component coating system is reduced to a base pressure having an order of magnitude of a few mTorr (e.g., a minimum range is below 50 mTorr). A lower base pressure is desirable, but depends on several considerations including, but not limited to: machine hardware configuration, size, shape, component material, process productivity, and industrial throughput. The base pressure can vary from 1 mTorr to 1000 mTorr.

The reduction to the base pressure is accomplished by completely opening the throttle valve (3,108) of the pumping system (4,109). Ar is injected into the vacuum chamber (1) through the components (5,6,8), for the case of the multi-component coating system. Ar is injected into the component (101), for the case of the single component coating system. The gas arrives from the gas supply (18,111) from the stored gas cylinders (112), through the valves (113,115) and the MFC (114), via the mixing box (20,116) and the gas line (21,117). The injected Ar has a flow in the range of 100-300 sccm. The pressure is regulated in the range of 100-200 mTorr by means of the throttle valve (3,108). Whilst Ar is flowing, a negative pulsed bias is applied to the component (6, 101) and a positive pulsed bias to the central electrode (7,106) (frequency 0, 5-20 kHz) to create an Ar plasma. The negative bias will attract Ar ions towards the surface of the component (6,101) while allowing ion bombardment and sputter cleaning of the component's (6,101) internal surface. Pressure is indicative of and depending upon the configuration of the single component coating system and the multi-component coating system. The stated gas flow range is meant for the single component coating system and must be scaled proportionally according to the number of components (6) employed by the multi-component coating system.

In some embodiments, an intermediate layer (e.g., comprising silicon (“Si”) rich C-coating) is deposited by flowing contemporarily an inert carrier gas (e.g., Ar) at a rate of 10-200 sccm, a C-containing precursor (e.g. acetylene) at a rate of 25-250 sccm and a metal or metalloid containing precursor (e.g. TMS) at a rate of 5-25 sccm. The reason for this step is to deposit a layer that can interact at the interface with the component (6,101) by creating iron-silicide bonding to increase coating adhesion. TMS, Ar, and acetylene are stored separately within the gas panel (18,111). Gases flow to the mixing box (20,116) where they mix before getting streamed for coating. The TMS, Ar, and acetylene are each stored separately in one of the gas cylinders (112). In the case of the multi-component coating system, the mixed gas flows through the gas splitter (22) and reaches different positions by means of dedicated lines (23,24,25). The coating is deposited by PECVD using a negative pulse bias applied to the component (6,101). TMS at room temperature is a liquid with very high vapor pressure introduced into the mixing box by vapor draw. This specific layer may be deposited in three different steps by varying the power supplied to the DC generator and the pulse frequency. By changing these parameters, in the range of 10-500 W (of power) and 3-20 kHz (frequency), the energy transfer of the deposition process is modulated, allowing the design of different coating architectures. As an example, an initial high-power, high-frequency gripping stage, followed by an intermediate low-power lower-frequency stage, capped by a final layer produces the plasma with same pulse frequency but at a higher power. Over the whole deposition of the intermediate layer, the temperature is kept in the range 100-200° C. The indicated power levels refer to the process of a single pipe and may vary proportionally to the actual number of processed pipes. The processing temperature is suggested for maximizing coating adhesion, but it may vary according to the configuration of the single component coating system and the multi-component coating system.

Once the intermediate adhesion layer is deposited, the C-rich coating may be produced by means of acetylene (e.g., as coating precursor) and Ar (e.g., as an inert gas carrier) only plasma. This step is quite analogous to the previous, differentiated only by the removal of the TMS and the increase in the acetylene content in the reacting gas mixture. Although the gas mixture has changed, the overall pressure is regulated to remain substantially unchanged through the throttle valve (3,108). The applied power, duty frequency, and temperatures remain within the same ranges. The use of acetylene does not rule out the option of using other C-containing precursors, for example hydrocarbons (CₓH_{y}) (such as methane (CH₄)) or diamondoids.

Without wishing to limit the present invention to any theory or mechanism, it is believed that the methods of the present invention allow for a deposition rate of up to about 20 microns per hour. Moreover, despite using gases such as acetylene (with chemical bonding not as strong as those present in diamondoids precursors), good coating uniformity (in terms of thickness and chemistry) may be achieved along the whole length of the component (6,101). This uniformity is obtained because of the symmetry of the coating process, which foresees the presence of a center electrode (7,106) placed in the cylindrical axis of symmetry of the component (6,101) (preferably over the whole length of the component (6,101)). The uniformity may also be the result of the fine tuning of the process parameters (such as the duty cycle), which allows the correct refill of freshly un-reacted gas, as well to the progressive coating of the center electrode (7,106).

In some embodiments, the conducting center electrode (7,106) comprises a metallic rod. The metallic rod may be sputtered to create a metallic layer on the substrate, or in the growing coating.

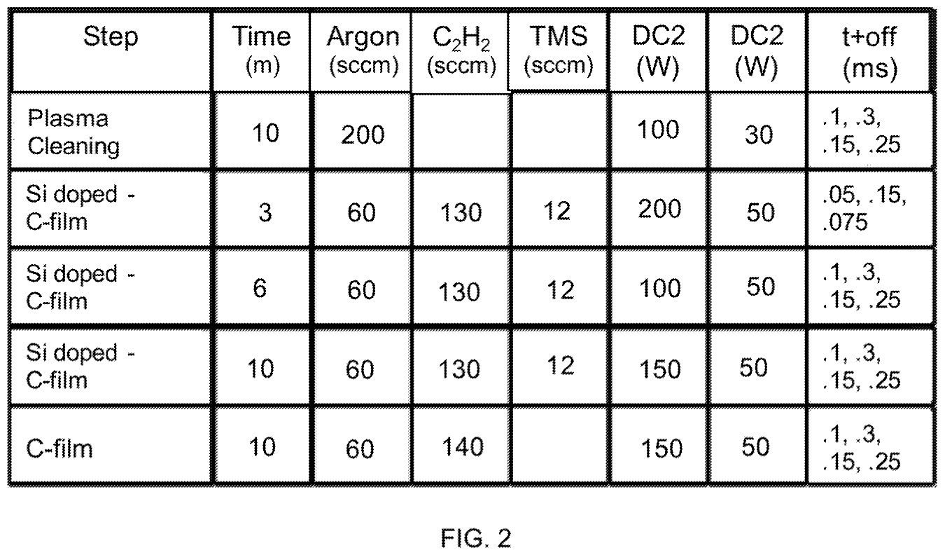

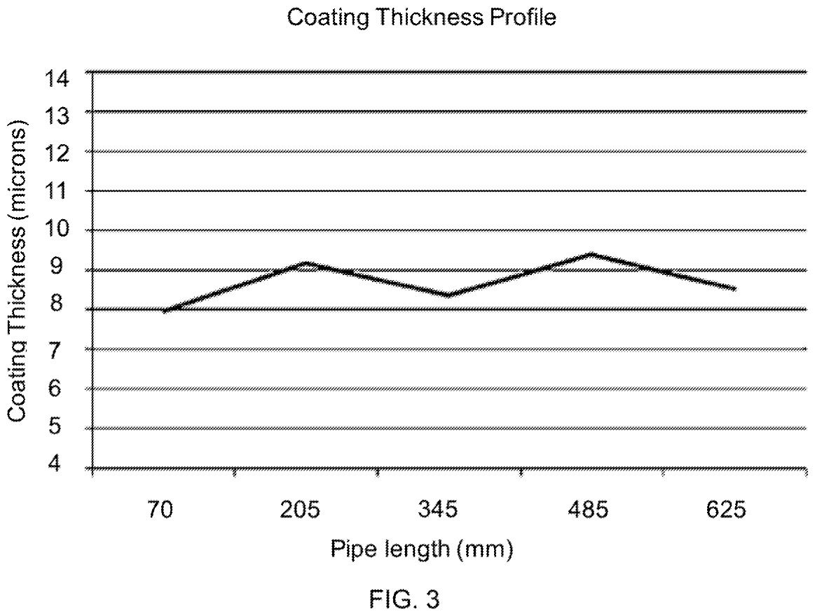

A non-limiting example of the method of the present invention is outlined in FIG. 2. FIG. 3 shows a thickness profile evaluation obtained on a coating deposited on a 28″ (710 cm) long, 2″ wide pipe. The excellence of the thickness uniformity is demonstrated as the entire coating is within 10% of the average value.

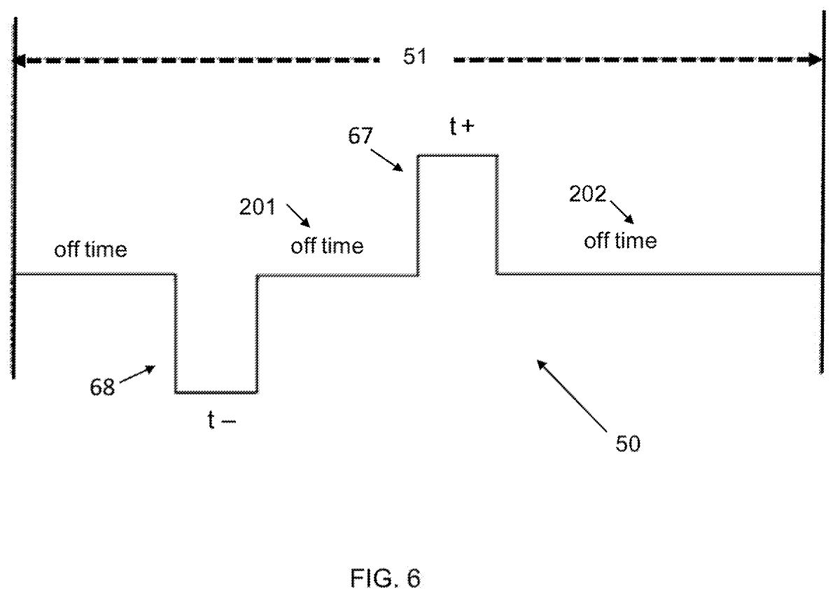

FIG. 6 shows an exemplary pulse voltage profile according to one embodiment of the invention. The bipolar voltage pulse (50) is applied between the center electrode (7,106) and the cylindrical electrode (6,101). In one embodiment, neither the center electrode (7,106) nor the cylindrical electrode (6,101) is grounded and the bipolar voltage pulse is applied between the center electrode (7,106) and the cylindrical electrode (6,101). In another embodiment, the cylindrical electrode (6,101) is grounded and the bipolar voltage pulse is applied to the center electrode (6,101). In yet another embodiment, the center electrode (7,106) is grounded and the cylindrical electrode (6,101) is applied with the bipolar voltage.

The bipolar voltage pulse (50) comprises a positive DC pulse (with a positive pulse amplitude t+ (67)) and a negative DC pulse (with a negative pulse amplitude t-(68)). The positive DC pulses and negative DC pulses are sequentially applied. In some embodiments, there is an interval t_{off} (202) between the positive DC pulse and the negative DC pulse. The bipolar voltage pulse (50) has a period (51) corresponding to the time interval between the instant of a negative (or positive) pulse and the next negative (or positive) pulse. The frequency of the bipolar voltage pulse (50) is referred to as the inverse of the period (51). The positive pulse amplitude and the negative pulse amplitude may or may not be the same. In one embodiment, the bipolar voltage pulse (50) has a uniform frequency, uniform positive pulse amplitude, and a uniform negative pulse amplitude. In another embodiment, the bipolar voltage pulse (50) has a variable frequency, variable positive pulse amplitude, and a variable negative pulse amplitude. The varying patterns of the frequency, pulse amplitude, and pulse amplitude may be pre-determined or adjusted dynamically according to selected parameters, such as discharging power, DLC deposition rate, etc.

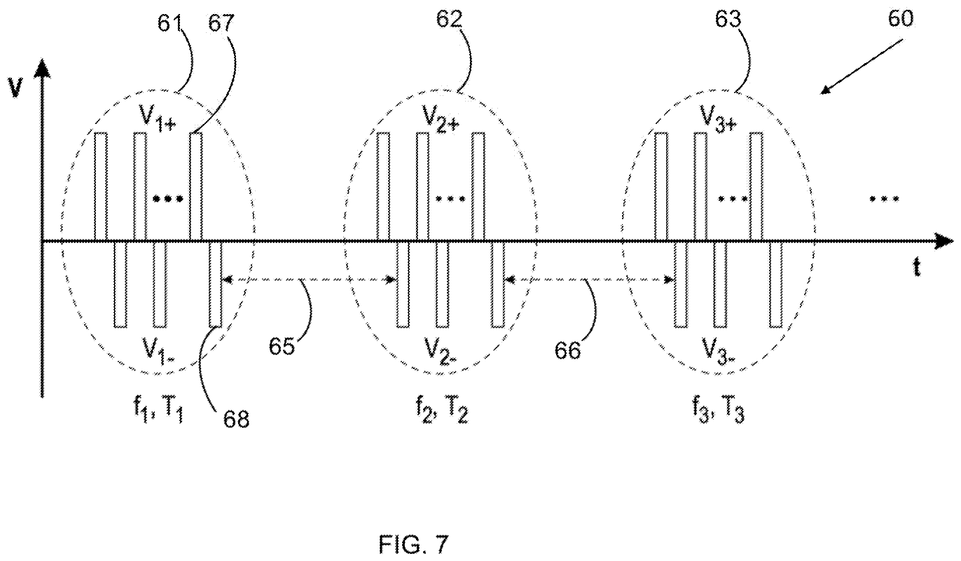

FIG. 7 shows another exemplary pulse voltage profile according to one embodiment of the invention. The bipolar voltage pulse (60) is applied between the center electrode (6,101) and the cylindrical electrode (7,106). The bipolar voltage pulse (60) comprises a plurality of discharge intervals with each discharge interval itself having a plurality of bipolar voltage pulses. As shown in FIG. 7, the first discharge interval (61) has a plurality of bipolar voltage pulses with a first frequency f₁ and a first discharge time T₁. Preferably, the first discharge interval (61) has a uniform positive pulse amplitude V₁₊ and a uniform negative pulse amplitude V₁₋. The second discharge interval (62) has a plurality of bipolar voltage pulses with a second frequency f₂ and a second discharge time T₂. Preferably, the second discharge interval (62) has a uniform positive pulse amplitude V₂+ and a uniform negative pulse amplitude V₂. The third discharge interval (63) has a plurality of bipolar voltage pulses with a third frequency f₃ and a third discharge time T₃. Preferably, the third discharge interval (63) has a uniform positive pulse amplitude V₃+ and a uniform negative pulse amplitude Vs. Between the first discharge interval (61) and the second discharge interval (62) is a first off time interval (65). Similarly, between the second discharge interval (62) and the third discharge interval (63) is a second off time interval (66). The first off time interval (65) and the second off time interval (66) may or may not be the same.

The bipolar voltage pulse (60) shown in FIG. 7 has many parameters which may be adjustable for discharging process control to ensure desired deposition characteristics, such as deposition rate and uniformness, etc. For example, the first discharge interval (61) may have a power of 300 watts (depending on the first frequency f₁, the first positive pulse amplitude V₁₊, and the first negative pulse amplitude V₁₋) and may last for 1 minute. After a 50 ms first discharge interval (61), the second discharge interval (62) starts, which may have a power of 150 watts (depending on the second frequency f₂, the second positive pulse amplitude V₂₊, and the second negative pulse amplitude V₂−) and may last for 2 minutes. After a 100 ms second discharge interval (62), the third discharge interval (63) starts, which may have a power of 50 watts (depending on the third frequency f₃, the third positive pulse amplitude V₃₊, and the third negative pulse amplitude V₃₋). After a 150 ms third discharge interval, the bipolar voltage pulse repeats again with the first discharge interval (61).

In some embodiments, the off time intervals (65, 66) may be regulated or chosen to accommodate discharge gas delivery. In the case of the multi-component coating system, during the off time intervals, the throttle valve (3) is ON to pump away the gas within the vacuum chamber (1) and the gas delivery system is ON for discharge gas (including carrier gas and precursors) delivery or replenishment. The off time intervals are chosen to preferably be at least the same time interval as the gas replenishment process.

In some embodiments, the discharge time (including the first discharge time, the second discharge time, the third discharge time, etc.) may be regulated to take into consideration the precursor consumption rate, which may be an empirical, a calculated, or a measured parameter. Preferably, the discharge interval is stopped before the depletion of the precursor for desired deposition characteristics.

Although FIG. 7 only shows three discharge intervals, one skilled in the art will recognize that various implementations and embodiments may be used for the bipolar voltage pulses. All of these implementations and embodiments are intended to be included within the scope of the invention.

Samples produced using methods and/or systems of the present invention have been submitted to Neutral Salt Spray test to assess corrosion resistance. The results show that the C-containing deposit of the present invention is able to resist as much as 20 hours before showing the first initial oxidation spots. Only after more than 40 hours do the number of spots increases substantially, although not showing a dramatic corrosion of the material comprising the component (6,101). For a Cr plated specimen, many initial corrosion spots appear within 5-6 hours of test, and afterwards corrosion increases drastically.

### Example

A process for the multi-component coating system is described in the present example and, since it is scalable to industrial applications without intellectual modifications to the coating process (e.g., full PECVD with plasma ignited inside the component cavity) or to the most innovative parts of the equipment design (e.g., coaxial center electrode), the process is intended for patenting independent of the equipment utilized for its realization. Thus, with minimal adjustments, the following process may be performed by the single component coating system of the present invention and/or similar tools.

Step 1: The vacuum chamber (1) is assembled according to the configuration of FIG. 1 by bolting the pipe-like component to be processed (6) (or containing the pieces to be processed, where electrical contact between the pieces and the external pipe-like component is ensured) to the dummies and to the insulating parts. In this stage, it is important to correctly place the centering components as indicated in FIG. 1B.

Step 2: A conducting wire (7), used as the center electrode, is inserted from the top insulating component (5) and is positioned along the entire length of the pipe-like component. In this step, a critical aspect is making the conducting wire (7) go through the mechanical tool (9) to ensure its correct positioning along the longitudinal axis of the pipe-like component. Since the center electrode has to be electrically connected, in this design, the top part of the center electrode has to emerge from the insulating component (5), and so must be inserted through correct compression fittings. The bottom part of the center electrode is connected to the mechanical tool (9) to keep it in position during the whole deposition process.

Step 3: The vacuum chamber (1), as assembled in Step 1, is vertically placed on adequate fixtures and connected to remaining equipment as follows:
1) the gas distribution system (21,22,23,24,25) is connected to the insulating component (5) by making use of compression fittings;
2) the pumping system (4) is connected to the vacuum chamber (1) and to the throttle valve (3);
3) the center electrode (7) is electrically connected to the DC power supply (10) through the anode splitter (16a) which is connected to the pulser unit (13); and
4) the pipe-like component (6) is connected to the DC power supply (10) through the cathode splitter (16c), which is connected to the pulser unit (13).

Step 4: The pumping system is switched ON (roughing first and root afterwards) and, by carefully opening the throttle valve (3), the vacuum chamber (1) is evacuated to a base pressure below 50 mTorr.

Step 5: Outgassing of the vacuum chamber (1) to remove remaining moisture and or adventitious gaseous contaminant from the internal surface of the material to be processed (the pipe-like component or other symmetrically placed component disposed along the pipe-like component). To improve the outgassing, an inert gas such as Ar is made to flow from the gas system into the pipe-like component at a rate between 10 and 100 sccm per pipe-like component (6). The component is heated to temperatures between 100 and 200° C. by means of a heating system installed inside the vacuum chamber (1).

Step 6: Plasma cleaning of the surface of the pipe-like component (6) is achieved by injecting Ar from the gas system into the pipe-like component (6) at flow in the range of 100-300 sccm per pipe-like component (6). The pressure is regulated in the range of 100-200 mTorr by means of the throttle valve (3). Plasma is ignited by means of a glow discharge by applying a negative pulsed bias to the pipe-like component (6) and a positive pulsed bias to the center electrode (7) (frequency 0.5-20 kHz). The temperature of the vacuum chamber (1) is continuously monitored to remain in the range of 100-200° C. via the heating system. This step is made to last between 1 and 15 minutes

Step 7: Deposition of an intermediate layer (e.g., comprising Si rich C-coating) is achieved without shutting off the plasma generated during step 6. A simple re-adjusting of the gas mixture is accomplished by flowing an inert gas (e.g., Ar) at a rate between 10-200 sccm per pipe-like component), a C-containing precursor (e.g., acetylene) at a rate of 25-250 sccm per pipe-like component, and a metal or metalloid containing precursor (e.g., TMS) at a rate of 5-25 sccm per pipe-like component. The gas mixture is created in the mixing box (20). The pressure is regulated to a value in the range of 100-300 mTorr via the throttle valve (3). The coating is deposited by PECVD using a negative pulse bias applied to the component (6), whilst applying a positive pulse bias to the center electrode (7). The properties of the deposited film are continuously modulated by the gas mixture composition, the power supplied (between 10-500 W/pipe-like component), and the frequency used (e.g. 3-20 KHz). The temperature of the vacuum chamber (1) is continuously monitored to remain in the range of 100-200° C. by making use of the heating system. This step is made to last between 5 and 45 minutes

Step 8: Deposition of the top C-rich layer is accomplished without shutting off the plasma used in step 7. The C-rich coating of the top layer may be produced by modifying the gas reacting mixture in the vacuum chamber (1). Hence, the metal or metalloid containing precursor (e.g., TMS) line is closed (e.g., for the single component coating system by acting on the related MFC (114)) whilst the C-rich precursor (e.g., acetylene) and the inert gas (e.g. Ar) are left to flow in order to generate the plasma. The present step is quite analogous to Step 7, it is differentiated by the removal of the TMS and the enriching of the gas mixture in the C-containing precursor. Although the gas mixture changes, the overall pressure is regulated through the throttle valve (3) to remain substantially unchanged with respect to Step 7. The applied power, duty frequency, and temperatures remain within the same range as Step 7. This step is made to last between 5 and 45 minutes.

The disclosures of the following documents are incorporated in their entirety by reference herein: U.S. Pat. Nos. 1,886,218; 3,523,035; 4,641,450; 5,039,357; 5,728,465; 6,511,710; 8,105,660; 8,112,930.

Various modifications of the invention, in addition to those described herein, will be apparent to those skilled in the art from the foregoing description. Such modifications are also intended to fall within the scope of the appended claims. Each reference cited in the present application is incorporated herein by reference in its entirety.

Although there has been shown and described the preferred embodiment of the present invention, it will be readily apparent to those skilled in the art that modifications may be made thereto which do not exceed the scope of the appended claims.

Therefore, the scope of the invention is only to be limited by the following claims. Reference numbers recited in the claims are exemplary and for ease of review by the patent office only, and are not limiting in any way. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting of”, and as such the written description requirement for claiming one or more embodiments of the present invention using the phrase “consisting of” is met.

The reference numbers recited in the below claims are solely for ease of examination of this patent application, and are exemplary, and are not intended in any way to limit the scope of the claims to the particular features having the corresponding reference numbers in the drawings.

### REFERENCES

M. Audino, “Use of Electroplated Chromium in Gun Barrels”, DoD Metal Finishing Workshop, Washington, D.C., 22-23 May 2006, http://www.asetsdefense.org/documents/workshops/mfw-5-06/backgroundreports/6-gun_barrels-mike_audino.pdf

1.-29. (canceled)

30. An apparatus for coating an inner surface of an electrically conductive hollow tube (6), herein referred to as a hollow tube, disposed within a vacuum chamber (1), the apparatus comprising:
a. a first end cap (5), comprising a first electrically insulating material, having an opening for a gas supply (18);
b. a second end cap (8), comprising a second electrically insulating material;
c. a wire (7) passing through a center of the first end cap (5), wherein the hollow tube (6) is disposed between the first end cap (5) and the second end cap (8), wherein the wire (7) is electrically conductive and disposed at a center axis of the hollow tube (6);
d. the gas supply (18) connected to the opening of the first end cap (5), wherein the gas supply (18) fills the hollow tube (6) with a gas, wherein the gas is contained within the hollow tube (6) by the first end cap (5) and the second end cap (8), wherein the gas comprises a material which, when ignited by an electrical pulse, causes a carbon-based coating to be deposited on the inner surface of the hollow tube (6); and
e. a pulse biasing system (13), capable of generating a series of electrical pulses, having a negative output connected to the hollow tube (6) and a positive output connected to the wire (7), wherein the hollow tube (6) acts as a cathode and the wire (7) acts as an anode;
wherein the pulse biasing system (13) delivers a series of positive and negative electrical pulses to the wire (7) and the hollow tube (6), wherein an electrical field is generated between the hollow tube (6) and the wire (7) for igniting the gas to deposit the carbon-based coating on the inner surface of the hollow tube (6).

31. The apparatus of claim 30, wherein the wire (7) is centralized by a weight (9) when the hollow tube (6) is vertically oriented relative to a ground surface, wherein the weight (9) is applied at a lower end of the wire (7), or applied at the second end cap (8), or applied at the lower end of the wire (7) and disposed within the second end cap (8).

32. The apparatus of claim 30, wherein a gas mixer (20) is connected between the gas supply (18) and the hollow tube (6), wherein the material comprising the gas is a mixture of gaseous chemical components comprising inert gases and plasma-enhanced chemical vapor deposition (“PECVD”) precursor gases, wherein the gas mixer (20) mixes the gaseous chemical components in a fixed ratio.

33. The apparatus of claim 30, wherein the pulse biasing system (13) is capable of outputting the series of positive and negative electrical pulses at a plurality of power levels.

34. The apparatus of claim 33, wherein the series of positive and negative electrical pulses are separated by an off time (65, 66, 201, 202), wherein the off time (65, 66, 201, 202) varies with a length or height of each hollow tube, a power level of the plurality of power levels, or both.

35. The method of claim 46, wherein the plurality of power levels ranges from about 10 watts to about 500 watts.

36. An apparatus for coating an inner surface of a plurality of electrically conductive hollow tubes (6), herein referred to as hollow tubes, disposed within a vacuum chamber (1), the apparatus comprising:
a. a plurality of top end caps (5) capable of holding a plurality of hollow tubes (6);
b. a plurality of bottom end caps (8) capable of holding a weight of and centralizing a plurality of wires (7);
c. the plurality of wires (7), each passing through a center of each top end cap (5);
d. a gas splitter (22), connected between the gas mixer (20) and the plurality of hollow tubes (6), capable of distributing an equal amount of gas to each hollow tube; and
e. a plurality of gas flow controllers (24,25), each connected between the gas splitter (22) and one of the plurality of top end caps (5).

37. The apparatus of claim 36 further comprising one of the following:
i. an anode splitter (16a), electrically connected between the positive output of the pulse biasing system (13) and the plurality of wires (7), wherein the pulse biasing system (13) delivers a series of positive and negative electrical pulses to the anode splitter (16a); or
ii. a cathode splitter (16c), electrically connected between the negative output of the pulse biasing system (13) and the plurality of hollow tubes (6), wherein the pulse biasing system (13) delivers the series of positive and negative electrical pulses to the cathode splitter (16c); or
iii. the anode splitter (16a) and the cathode splitter (16c), wherein the anode splitter (16a) is electrically connected between the positive output of the pulse biasing system (13) and the plurality of wires (7), wherein the cathode splitter (16c) is electrically connected between the negative output of the pulse biasing system (13) and the plurality hollow tubes (6), wherein the pulse biasing system (13) delivers the series of positive and negative electrical pulses to the anode splitter (16a) and the cathode splitter (16c);
wherein the series positive and negative pulses are applied equally to each hollow tube, of the plurality of hollow tubes (6), and to each wire, of the plurality of wires (7), whereupon application of the series of positive and negative pulses, an electrical field is generated between each hollow tube and a wire disposed therein,
wherein the gas splitter (22) delivers gas to each gas flow controller (24, 25),
wherein each gas flow controller (24, 25) is either open or closed, wherein if a given gas flow controller is open, a corresponding hollow tube is filled with gas, wherein the corresponding hollow tube is coupled to the given gas flow controller via a top end cap, wherein when the electrical field is generated, if the corresponding hollow tube is filled with gas, the gas is ignited, causing a deposition of the carbon-based coating onto the inner surface of the corresponding hollow tube.

38. The apparatus of claim 37, wherein the pulse biasing system (13) is capable of outputting the series of positive and negative electrical pulses at a plurality of power levels.

39. The apparatus of claim 38, wherein the series of positive and negative electrical pulses are separated by an off time (65, 66, 201, 202), wherein the off time (65, 66, 201, 202) varies with a length or height of each hollow tube, a power level of the plurality of power levels, or both.

40. The method of claim 46, wherein the plurality of power levels ranges from about 10 watts to about 500 watts.

41. A method of coating an inner surface of at least one conductive hollow tube (6), the method comprising:
a. extending a conductive wire (7) through a center axis of the at least one conductive hollow tube (6);
b. idling the at least one conductive hollow tube (6) with a gas from a gas supply (18), wherein the gas comprises a mixture of chemical components which, when ignited, cause a carbon-based coating to be deposited on the inner surface of the at least one conductive hollow tube; and
c. supplying a bipolar voltage pulse (50, 60) to the at least one conductive hollow tube (6) and the conductive wire (7) disposed therein, wherein the bipolar voltage pulse (50, 60) ignites the gas, thereby depositing the carbon-based coating on the inner surface of the at least one conductive hollow tube (6).

42. The method of claim 41, wherein the conductive wire (7) is centralized with a weight (9) when the at least one conductive hollow tube (6) is vertically oriented relative to a ground surface, wherein the weight (9) is applied at a lower end of the conductive wire (7), or applied at an end cap attached to a lower end of the at least one conductive hollow tube (6), or applied at the lower end of the wire (7) and disposed within the end cap.

43. The method of claim 41, wherein the method is used for coating an inner surface of a plurality of conductive hollow tubes (6), wherein a conductive wire from a plurality of conductive wires (7) is extended through a center axis of each hollow tube (6), wherein when the plurality of conductive hollow tubes (6) is filled with the gas from the gas supply (18) and the bipolar voltage pulse (50, 60) ignites the gas, the carbon-based coating is deposited on the inner surface of each conductive hollow tube.

44. The method of claim 41, wherein the method is used for coating an inner surface of a plurality of conductive hollow tubes (6), wherein the plurality of conductive hollow tubes (6) are linearly aligned such that an end of one conductive hollow tube is fluidly connected to an end of another conductive hollow tube such that the center axis of each conductive hollow tube is aligned with the center axes of the other conductive hollow tubes, wherein the conductive wire (7) extends through the aligned center axes of the plurality of conductive hollow tubes, wherein when the plurality of conductive hollow tubes (6) is filled with the gas from the gas supply (18) and the bipolar voltage pulse (50, 60) ignites the gas, the carbon-based coating is deposited on the inner surface of each conductive hollow tube.

45. The method of claim 41, wherein a gas mixer (20) is connected between the gas supply (18) and the at least one conductive hollow tube (6), wherein the gas mixer (20) mixes the mixture of chemical components according to a fixed ratio, wherein the mixture of chemical components comprises inert gases and plasma-enhanced chemical vapor deposition (“PECVD”) precursor gases.

46. The method of claim 41, wherein the bipolar voltage pulse (50, 60) is supplied by a pulse biasing system (13).

47. The method of claim 46, wherein the pulse biasing system is capable of outputting a series of pulses at a plurality of power levels, wherein each pulse, of the series of pulses, is separated by an off time (65, 66, 201, 202).

48. The method of claim 46, wherein the off time (65, 66, 201, 202) varies with a length or height of the hollow tube (6), a power level of the plurality of power levels, or both.

49. The method of claim 46, wherein the plurality of power levels ranges from about 10 watts to about 500 watts.
